(19) United States
(12) Patent Application Publication
(10) Pub. No.: US 2009/0045826 A1
(43) Pub. Date: Feb. 19, 2009

(54) Measuring probe with optical cable

(76) Inventor: Samo Sustarsic, Colorado Springs, CO (US)

Correspondence Address: Samo Sustarsic, 3412 N. Jon Street, Colorado Springs, CO, 80907, US

(21) Appl. No.: 11/734,787

(22) Filed: Aug. 18, 2007

(51) Int. Cl. G01R 1/067

(52) U.S. Cl. 324/754

(57) ABSTRACT

Housing of measuring part of probe is made out of electrically non-conductive material, most common plastic;

Measuring tip must be made out of electrically conductive materials;
Cable containing measuring wire; electrically conductive most common Copper;
Fiber optical material is electrically non-conductive; electrically insulating material; Plug housing on the side of multimeter is made out of electrically nonconductive material—most common plastic;
Conductive plug on side of multimeter is made out of electrically conductive materials—most common Copper;
Optical cable is electrically non-conductive materials, fiber optic;

### CROSS-REFERENCE TO RELATED APPLICATIONS

not applicable

### STATEMENT REGARDING FEDERALLY SPONSORED RESEARCH OR DEVELOPMENT

not applicable

### THE NAMES OF PARTIES TO A JOINT RESEARCH AGREEMENT

not applicable

### INCORPORATION-BY-REFERENCE OF MATERIAL SUBMITTED ON A COMPACT DISC

not applicable

### BACKGROUND OT THE INVENTION

1) Field of Invention

optical

2) Description of Related Art Including Information Disclosed under 37 CRF 1.97 and 1.98

not applicable

### BRIEF SUMMARY OF THE INVENTION

My solution transports light with help of optical cable directly on measured object, without noticeable change in dimension of measuring probe;
source of light usually led can be located in multimeter, that eliminates separate power supply in measuring probe or usage of clip-on with separate power supply;
doesn't generates electrical induction—doesn't effect measured results;

### BRIEF DESCRIPTION OF THE SEVERAL VIEWS OF THE DRAWING'S

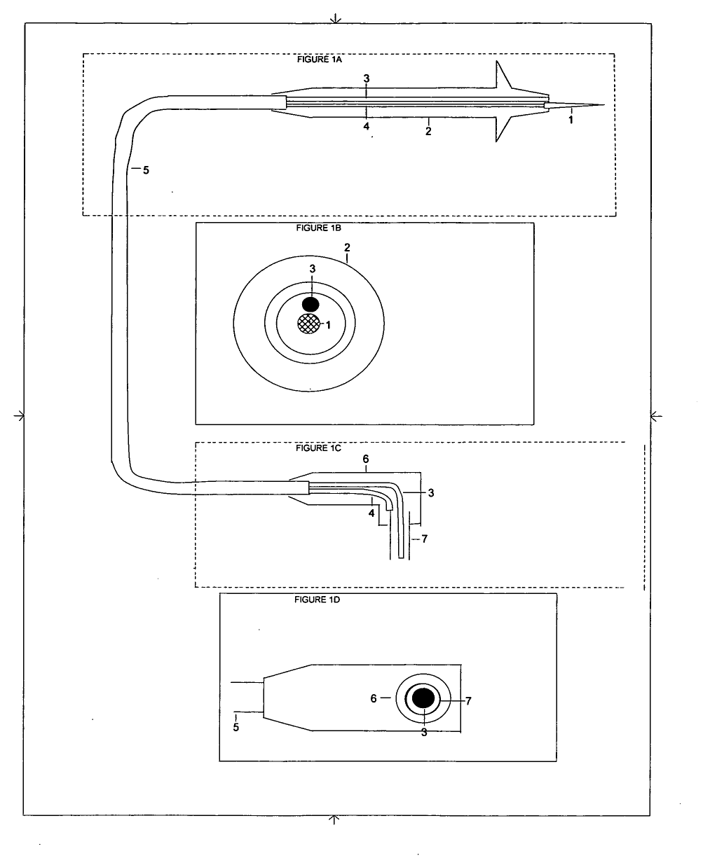

1) FIG. 1A (Side View of Measuring Probe):

typical measuring probe consisting of electrically non-conductive probe housing (2), electrically conductive measuring tip (1), electrically conductive wire (4) witch transports electrical values from electrically conductive measuring tip (1) to meter and optical cable (3).

2) FIG. 1B (Front View of Measuring Probe):

it consists of electrically non conductive probe housing (2) electrically conductive measuring tip (1), and optical cable (3).

3) FIG. 1C (Side View):

plug (plugs in multimeter) consist of electrically nonconductive plug housing (6) in Which you have optical cable (3), electrically conductive wire (4), and electrically conductive plug (7).

4) FIG. 1D (Front View):

plug (plugs in multimeter) consist of electrically nonconductive plug housing (6) in which you have optical cable (3) run thru electrically conductive plug (7) and electrically conductive wire (4).

### BRIEF DESCRIPTION OF INVENTION

Light is transported from multimeter to measured object with help of optical cable (3). Optical cable (3), runs thru electrically conductive plug (7), under which source of light needs to be located (not part of patent). Light is then transported thru optical cable all the way to measured object.

### DETAILED DESCRIPTION OF THE INVENTION

Principle. See blueprint
1. Electrically conductive measuring tip
2. Electrically non-conductive probe housing
3. Optical cable
4. Electrically conductive wire
5. Cable with wires (electrically insolated cable consisting optical cable (3) and electrically conductive wire (4)).
6. Electrically nonconductive plug housing
7. Electrically conductive plug

Light is transported from multimeter to measured object with help of optical cable (3). Optical cable (3), runs throe electrically conductive plug (7), under which source of light needs to be located (not part of patent). Light is then transported through optical cable all the way to measured object.

Optical cable (3) is running all the way threw electrically conductive plug (7), electrically Non-conductive plug housing (6), with the measuring electrically conductive wire (4) to the side of a electrically conductive measuring tip (1). Optical cable (3) and electrically conductive wire run inside the electrically insolated sleeve ((all three form cable with wires) electrically insolated cable consisting optical cable (3) and electrically conductive wire (4)).

### Improvement Against Existing Measuring Probe

Existing measuring probe is basically without light. My solution transports light directly on measured object, without noticeable change in dimension of measuring probe. Source of light usually LED can be located in multimeter. That eliminates separate power supply in it doesn't generates electrical induction.

Until now all you could use is normal flashlight or clip on light. Disadvantages are obvious, you don't throw shades on measured objects, you don't need separate power supply, no electrical induction, you don't need another person to hold light, dimensions of the measuring probe stay same.

1. Probe plug housing is made out of electrically nonconductive materials;
Cable insulation is made out of electrically nonconductive materials;
Optical cable is made out of electrically non-conductive materials;
Measuring wire is made out of conductive materials;
Measuring tip is made out of conductive materials;
Conductive plug is made out of electrically conductive materials;
